(19) United States
(12) Patent Application Publication
(10) Pub. No.: US 2008/0196758 A1
(43) Pub. Date: Aug. 21, 2008

(54) Portable, self-sustaining power station

(76) Inventor: Dennis McGuire, Stuart, FL (US)

Correspondence Address: MCHALE & SLAVIN, P.A., 2855 PGA BLVD, PALM BEACH GARDENS, FL, 33410, US

(21) Appl. No.: 11/965,422

(22) Filed: Dec. 27, 2007

Related U.S. Application Data
(60) Provisional application No. 60/882,054, filed on Dec. 27, 2006.

(51) Int. Cl. H01L 31/045; F03D 9/02; F03D 11/00

(52) U.S. Cl. 136/245; 290/55; 416/142

(57) ABSTRACT

A self-sustaining, portable, power station that may be moved by land, air, or sea to an area that has no utilities. The station is provided with at least one wind turbine and/or solar panel arrays in communication with at least one electrical distribution and storage means. The derived electricity is used to power various systems including, albeit not limited to, a communications system, a water filtration system, a water distribution system to allow the public to draw potable water and provide basic hygiene. The electricity derived may also be used to run outside systems, such as schools, hospitals, or the like.

### RELATED APPLICATION

This application is based upon provisional application 60/882,054 filed Dec. 27, 2006 the contents of which are incorporated herein.

### FIELD OF THE INVENTION

This invention relates to a portable and self-sustaining power station; particularly, to a power station for producing and distributing electrical power, potable water, and other services to areas that have no operating utilities.

### BACKGROUND OF THE INVENTION

In the aftermath of the disastrous events of Sep. 11, 2001 and hurricane Katrina, the emergency response capability of most governmental agencies charged with such a mission has undergone a thorough review. After reviewing the tools and programs available to emergency response agencies (police, fire and rescue departments, hospitals, etc.) of local, state, and the federal government, certain inadequacies were uncovered. It became readily apparent that certain deficiencies persisted in treating large-scale disasters, including the lack of specifically designed equipment capable of being immediately deployed into disaster areas to supply basic needs for the inhabitants, such as water, electricity, telecommunications, etc. Such inadequacies include the inability of the survivors to reach relief supplies, the inability of the relief supplies to reach the survivors, and the lack of facilities to help the survivors and/or workers rebuild the infrastructure. Similar problems locating potable water and electricity are encountered daily by the inhabitants of developing and third world countries and/or those countries currently at war.

The use of large scale equipment, such as that employed by the U.S. government following Hurricane Katrina, produced potable water. However, survivors could not reach the location where the equipment was placed. Such equipment must be placed throughout the community so that the individuals residing in the community can reach such equipment on foot, and carry water from the equipment by hand.

There exist a multitude of mobile and portable power stations that supply electricity to field hospitals, emergency aid units, and water filtration systems. Most of these stations rely solely on generators which use fossil fuels (e.g., diesel oil) for generating electricity. However, these fossil fuels must be constantly replenished and their combustion releases harmful pollutants into the environment. Some of these portable stations also include tanks containing potable water or they are adapted to hook up to a supply of potable water. Since these limited resources often run out before the emergency situation has abated, portable and self-reliant stations have been designed which depend on wind turbines and/or solar cell panels for generating and storing electrical energy.

For example, U. S. Pre-grant publication No. 2006/01373348, to Pas, discloses a mobile power station provided with a wind turbine and/or solar cell panel containing solar cells and storage elements for storing electrical energy. The storage elements include a battery as well as a hydrogen system having a hydrogen generator, tank, and cell for generating electricity by combustion of hydrogen.

Similarly, the “Mobile Power Station TM” MPS is a self-sufficient power station housed in a standard shipping container. It includes at least one wind turbine and solar panels for self-generated power. Like the present invention, the MPS can be transported by truck, train, ship, plane or parachuted by plane. However, unlike the present invention, the MPS requires the use of the telescoping arms and solar panels which must be carefully assembled on the side of the container by a crew. The asymmetrical arrangement of the top panels on the top of the container can act as a sail that may tip the container during windy conditions.

None of the aforementioned prior art disclose the space saving arrangement of solar panels in the stowed position on top of the container of the inventive station. Nor does the prior art teach or suggest symmetrically arranging the solar panels in the deployed position to enhance the stability of the station. The symmetrical arrangement of the solar panels provides lateral stability to the station, without the need for an auxiliary support system used in Pas station, as described above. The solar panels of the present invention are constructed and arranged in a manner that maximizes the surface area exposed to the sun. Furthermore, the solar panels are arranged such that they may be easily and readily stowed inside or on top of the container when not in use or during transport of the station.

What is lacking in the art is a portable and self-sustaining power station that can be positioned within the disaster zone or a remote location and provides an electrical power system, a water treatment system capable of converting contaminated water into potable water, a water distribution system, and a telecommunications system.

### SUMMARY OF THE INVENTION

Disclosed is a self-contained power station that may be moved by land, air, or sea to an area that has no operating utilities. The power station is provided with at least one wind turbine, at least one solar cell panel in communication with at an electrical distribution means and/or least one storage means capable of storing the energy generated by the wind turbine and the solar cell panels. The station employs at least one engine capable of operating a complete communications suite and water treatment equipment capable of making potable water from most sources of water, such as polluted reservoirs, lakes, streams, and fire hydrants and at least one generator. The station also includes a water distribution system to allow the public to draw potable water. The power station generates sufficient power to operate pumps to draw in and out the water but is efficiently sized to provide extended operation on minimal fuel.

Accordingly, it is a primary objective of the instant invention to provide a power station which supplies work space, living space, battery storage, at least one water treatment system, electricity, and telecommunications system. The entire station may be transported by rail, land vehicle, air lift, and water.

Another objective of the present invention is to provide a power station that includes a solar panel array that can be quickly and easily deployed by a single person.

Still another objective of the present invention is to provide a power station in the form of a freight or marine container. This type of container is designed to float if dropped in water making it particularly useful if the water level on land rises, as often happens during a hurricane or flood.

It is another objective of this invention to provide a modular raw water treatment system for producing potable water that uses multiple treatment processes to neutralize or remove contaminants in the raw water available at the site and generated during site cleanup or decontamination activities providing area inhabitants with drinking water and showering facilities. This system is the subject of U. S. patent application Ser. No. 11/075,844 and 11/264,659 both to McGuire, and are herein incorporated by reference in their entirety.

It is yet another objective of the instant invention to provide the station with environmental controls including air filtering, heating and cooling.

Still another objective of the present invention is to teach solar panels which are symmetrically arranged solar panels when in the deployed position to provide enhanced stability to the station, especially during windy conditions.

It is still another objective of the invention to teach the use of power stations that are sized to provide community support for areas that have little or no access to transportation by providing necessities that can be reached by foot.

Other objectives and advantages of this invention will become apparent from the following description taken in conjunction with the accompanying drawings wherein are set forth, by way of illustration and example, certain embodiments of this invention. The drawings constitute a part of this specification and include exemplary embodiments of the present invention and illustrate various objects and features thereof.

### BRIEF DESCRIPTION OF THE FIGURES

FIG. 1 is an upper perspective view of the portable power station according to one embodiment of the invention, with the solar panels and wind turbine in the deployed position;

FIG. 2 is an upper perspective view of the portable power station with the top panel removed so that the interior chamber is revealed;

FIG. 3A is an upper perspective view of the portable power station according to another embodiment of the invention, with the solar panels shown in the deployed position;

FIG. 3B is another upper perspective view of the portable power station according to the embodiment of FIG. 3A;

FIG. 4A is an upper perspective view of the portable power station, with the solar panels shown in the deployed and tilted position;

FIG. 4B is another upper perspective view of the portable power station according to the embodiment of FIG. 4A;

FIG. 5 is an upper perspective view of the portable power station with the solar panel arrays in the stowed position;

FIG. 6A is a side view of the power station along the longitudinal length of the station;

FIG. 6B is a side view of the power station opposite that seen in FIG. 6A;

FIG. 6C is another side view as seen along the A-A axis of FIG. 6B;

FIG. 7A is upper perspective view of the portable power station with the panels stowed in their respective compartments;

FIG. 7B is another upper perspective view of the portable power station of the size opposite FIG. 7A with the panels in the stowed position;

FIG. 8 is an upper perspective view of the portable power station according to another embodiment of the invention including a communication satellite dish attached to the top of the container; and

FIG. 9 is an upper perspective view of the portable power station according to another embodiment of the invention including retractable legs for providing additional support to the solar panels.

### DETAILED DESCRIPTION OF THE INVENTION

Detailed embodiments of the instant invention are disclosed herein, however, it is to be understood that the disclosed embodiments are merely exemplary of the invention, which may be embodied in various forms. Therefore, specific functional and structural details disclosed herein are not to be interpreted as limiting, but merely as a basis for the claims and as a representation basis for teaching one skilled in the art to variously employ the present invention in virtually any appropriately detailed structure.

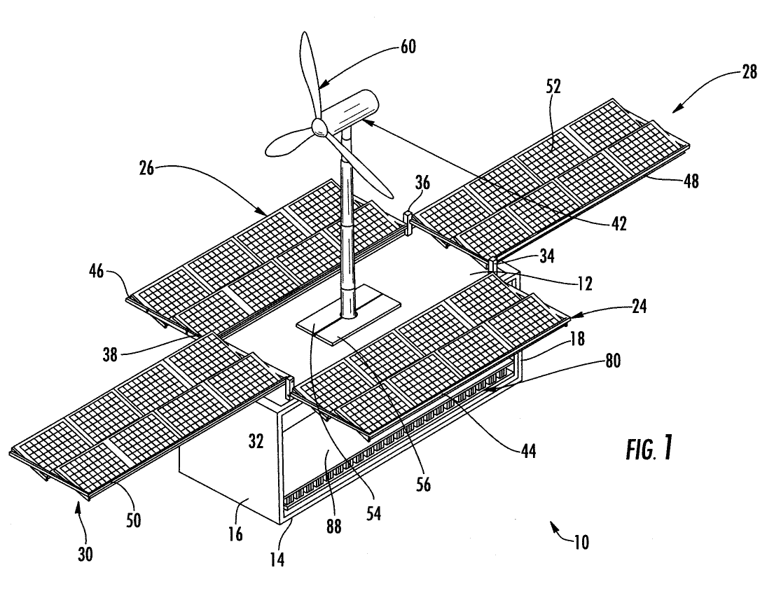

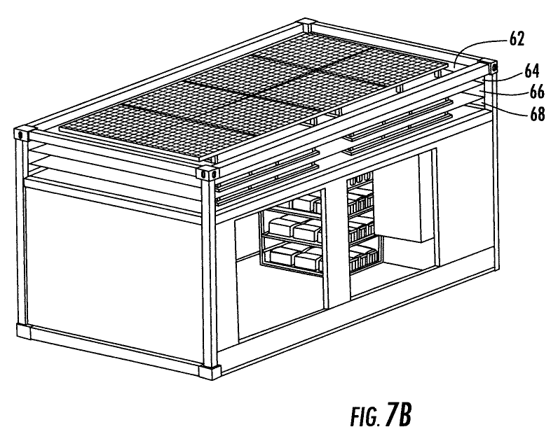

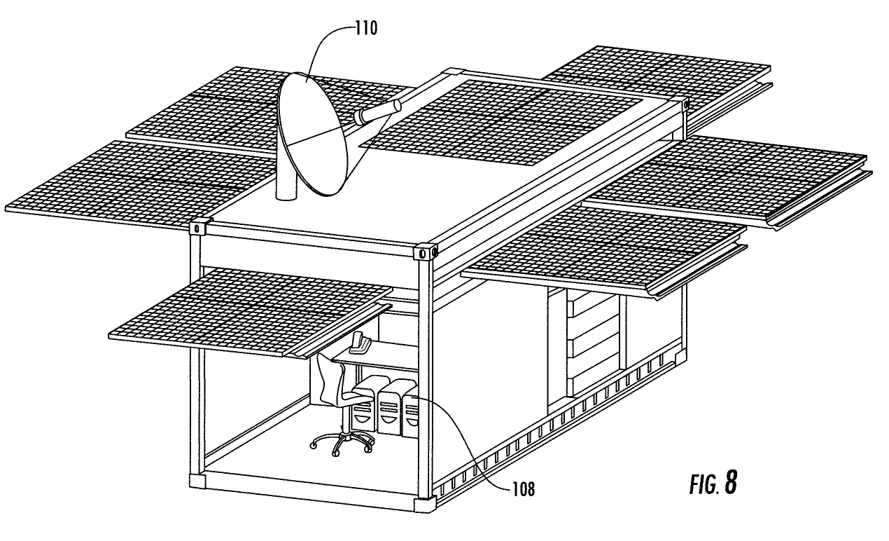

Referring now to FIGS. 1-9, wherein like elements are numbered consistently throughout, FIG. 1 illustrates one embodiment of the inventive power station, generally referenced as 10. The station is in the form of a container with a top panel 12, bottom panel 14, two pairs of oppositely disposed sidewall panels (16, 18) (20, 22) forming an interior chamber 40. Although depicted here as a rectangular station, is it within the purview of the invention to provide a station in any shape, such as, square. The container is of sufficient strength and rigidity to support the weight of the building and its contents without significant deformation.

According to a preferred embodiment, the container is a previously used standard ISO container (also called a marine shipping container). Thus, the ISO container is recycled after use making it cost effective and good for the environment. Shipping containers are generally designed to float, should it fall off the boat en route to their destination, making it particularly suitable for use during a hurricane, or flood. Any size container may be utilized, for example, the building structure may be a 20 ft., standard ISO container with inside measurements of 20 ft. long, 8 ft. wide, and 8.5 ft. high. Other container sizes are contemplated herein, e.g., 30 ft., 40 ft.

The container is modified such that it has solar panel arrays (24, 26, 28, 30) pivotally attached along the upper perimeter of the top of the container and at least one wind turbine 42 extending through the top panel (as discussed further below). These solar panels are used to capture energy from the sun for immediate use or storage via any suitable electric storage means (e.g., battery), as is well known in the art. Each solar panel array is pivotal between a deployed position, as shown in FIG. 1, and a stowed position. For example, as shown in FIG. 1, the top of the container has rigidly attached and upwardly extending posts (32, 34, 36, 40) located proximate to the four corners of the top panel.

Each of the solar panels includes a rigid frame (44,46,48,50) attached at one end to posts located on each corner of the container by any pivotal means of attachment known in the art (e.g., hinge, pin, etc.) For example, the first panel array 24 is the attached to the posts 32, 34 at a height closest to the top panel of the container. The second solar panel array 26 is pivotally attached to posts 36, 38 further up from the first. Likewise, the third solar panel array 28 is located higher along the posts 34, 36 than the second. The last panel array 30 located is the highest point along the posts 32, 38. In this manner, the panels are able to fold one on top of the other on the upper surface of the top panel of the container. This provides for easy and safe storage for the panels during transport of the station.

Each panel array includes individual solar cells on one side (underside). The panel arrays are rotated around their pivot means to the deployed position, as seen in FIG. 1, thereby exposing the solar cells disposed underneath to radiant energy from sun. The deployment and stowing of these panels is easily accomplished by a single person since it does not require assembly of solar panel supports or arms like that seen in the prior art. However, retractable support legs 112 may be used like those seen in see FIG. 9.

It is important to note that the deployed solar panels are symmetrically arranged along the upper perimeter of the container in order to uniformly balance the station and provide enhanced lateral stability thereto. This uniformity of weight helps to prevent the station from tipping over, especially when strong winds are acting against the wind turbine, discussed further below.

As discussed above, each of the solar panels arrays are housed in a substantially rectangular, planar, and rigid frames. The rigid frames have a width and length dimension that is less than or equal to that of top panel for compact and easy storage. The solar panels include at least one linear array of panels pivotally attached at about the midpoint of both ends to the frame by any suitable pivot means (e.g., hinge, pin) from 0 to about 45 degree tilt capacity. Thus, once the solar panels arrays are deployed, this unique arrangement allows the user to easily pivot each linear array 52 from a substantially flat position (along the plane of the frame) to an angle that provides optimum interception of incident solar radiation on either side of the station without the need for support braces, extender arms, or the like, which are used to fix the solar panels to the desired angle, like that seen in the prior art. Each linear array is composed of a plurality of individual solar cells, preferably high efficiency like those manufactured by (SANYO INC.).

The wind turbine 60 reversibly expands from a stowed position to a deployed position (FIG. 1) via a rigid telescoping mast 54. When fully stowed, the wind turbine and mast are housed inside the interior of the container. When deployed, the mast extends through an aperture formed at a generally centralized location in the top panel of the station for stability, see for example FIG. 9. The mast and wind turbine are constructed and arranged to withstand at least 100 MPH winds. The aperture may be at least partly closed by two plates (56, 58) each having a cutout portion for laterally stabilizing the mast. The base of the mast is secured to the floor of the container. The telescoping mast allows the turbine to be positioned to any desired height above the station. The wind turbine also includes detachable blades 60 for easy storage when the unit is being transported inside the interior chamber of the container. Like the solar panels above, the turbine harnesses energy from the wind for use immediately or deposit in electrical storage means (battery), as is known in the art and need not be explained in detail. The energy stored in the batteries can then be utilized when there is little sunlight or wind. In addition, the station is provided with at least one generator/ engine 84 and associated fuel tank 86 for storing fuel (e.g., diesel) for peaking or supplemental power when the solar panels, wind turbines and electrical storage means are not sufficient.

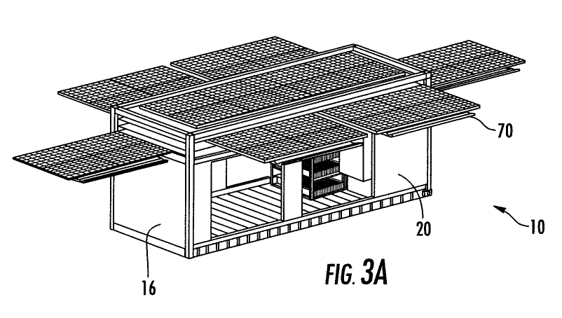

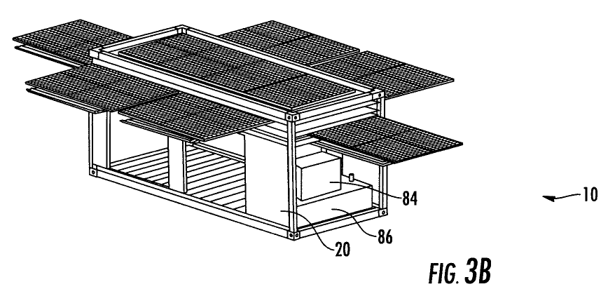

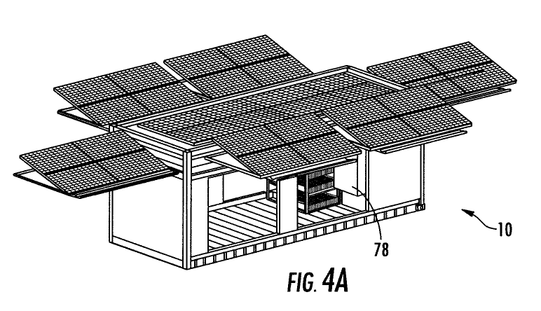

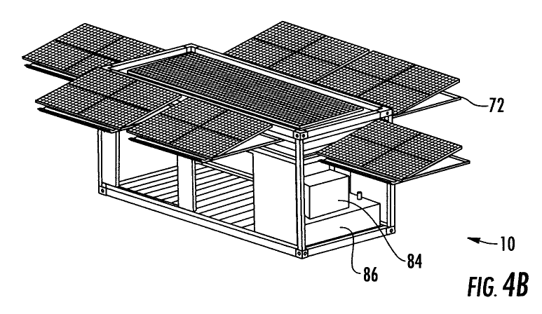

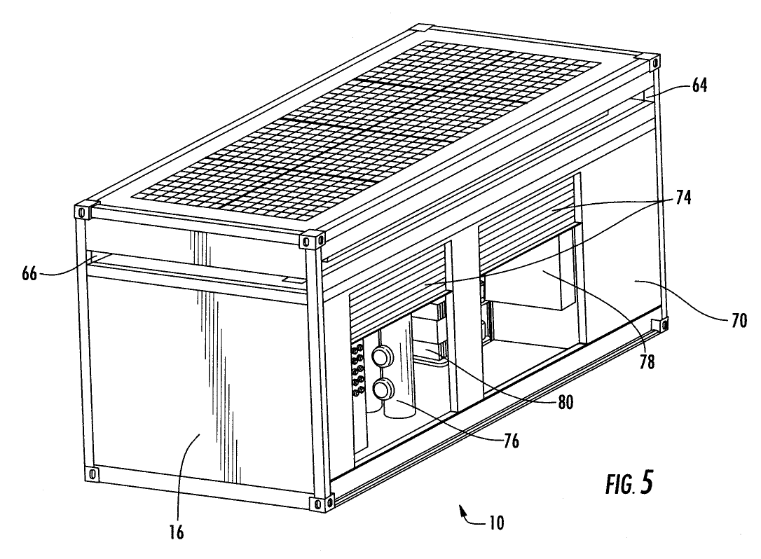

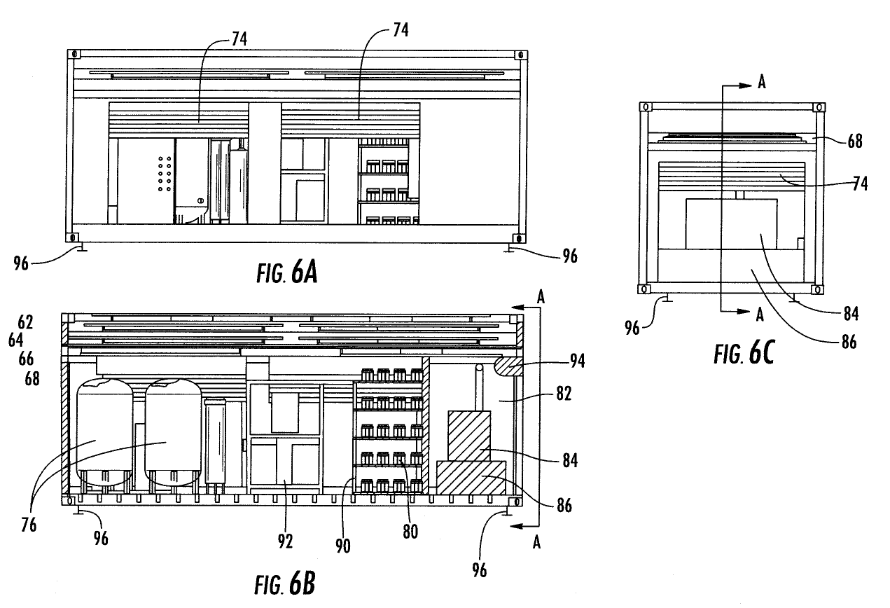

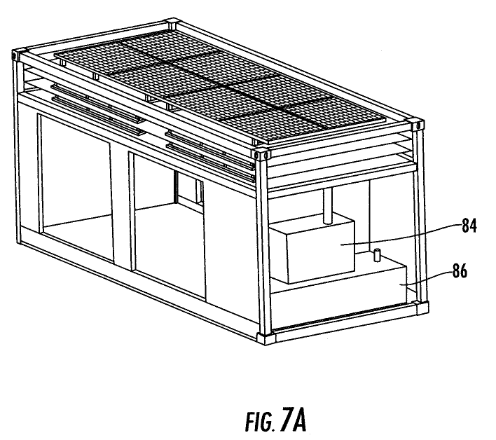

According to another embodiment, illustrated in FIGS. 3a-9, the container may be designed with a different solar panel deployment system capable of withstanding high wind conditions, like those encountered after a hurricane. Similar to the previous embodiment described above, the solar panels are symmetrically arranged along the upper perimeter of the container in the deployed position, which helps prevent the station from tipping over. The container is designed with separate compartments (62, 64, 66, 68) each for housing a solar panel array (best seen in FIGS. 6A-C). FIGS. 3A-B illustrate the solar panels in the deployed position. FIGS. 4A-B illustrate the solar panels in the deployed and angled position. Any suitable tilting mechanism capable of arranging the solar panel arrays to the desired angle may be used.

Similar to the previous embodiment, the solar panels arrays are housed in a rectangular, planar, and rigid frame 72 having a width and length dimension that is less than or equal to that of top panel for compact and easy storage within the compartments, see FIG. 5. Each of these solar panel arrays is attached to a panel slide mechanism. Only the solar panel array in the uppermost compartment do not include any slide mechanism and remain stationary and do not tilt during use. One example of a suitable sliding mechanism may include a pair of rollers installed in the compartment at a dimension corresponding width or length of the solar panel array. The arrays easily slide within the track attached to the sides of the panel arrays, in a manner similar to that used in a desk drawer. Obviously, this arrangement of rollers and tracks could be reversed without departing from the scope of the invention.

Referring now to FIGS. 6A-B which illustrate a cross-sectional view of the power station according to this embodiment, the upper portion of the container has four compartments at different levels or heights relative to the top surface of the container, with solar panels housed inside for protection during transport. These compartments also include locking means (not shown) to prevent the solar panel arrays from sliding out unintentionally during transport.

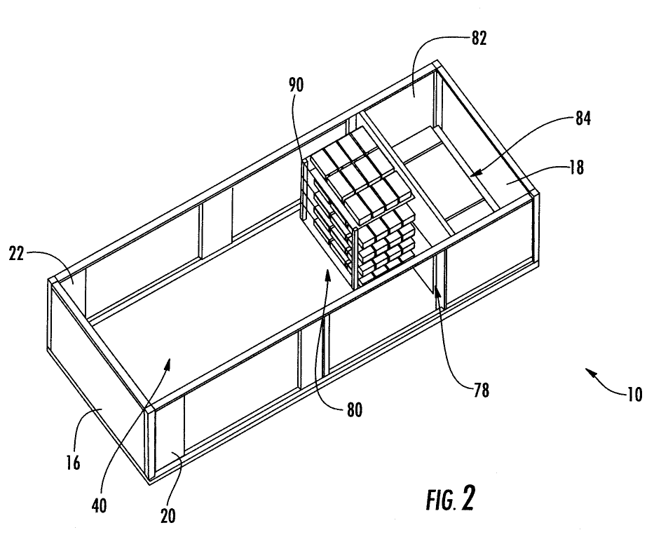

Any of the aforementioned embodiments of the power station may include windows (not shown) or access doors 74 for ingress and egress and for viewing the surrounding area. The container interior may also be divided up into different areas for housing the water filtration system 76, control panels (e.g., main power distribution panel) 78, battery packs 80, main electrical panel, etc. (see FIGS. 5-7B) . As shown in FIG. 2, the station may also include at least one small compartment 82 which is insulated for sound and designed to include a generator 84 and/or fuel tank 86 (e.g. may include vent 94 with air filter system to expel generator fumes). One or all of the windows may be sealed or openable and the access doors may be roll-up type, as shown in FIG. 5. The container may be mounted on wheels (now shown), as a towed vehicle or it may be self powered with a driving station (not shown). The station may be moved on a trailer or airlifted in the hold of an aircraft or suspended by sling. The wheels may be re moved to facilitate shipping and installation on a site. Rollers may be included on the bottom of the building to facilitate loading of the structure into the transporter. In addition, the bottom surface of the building structure may be sealed to allow movement by water, such as on the deck of a boat or towed by small boat with pontoons temporarily or permanently affixed to the bottom (not shown)

In order to conserve o n space, the floor of the station may be raised to create an area designed for housing the storage batteries (see FIG. 1). The raised floor makes it easy for mounting of power system controls and auxiliary equipment modules. Otherwise, the batteries may be housed on rack 90 inside the container (see FIG . 2). The batteries are secured to the racks by straps or the like.

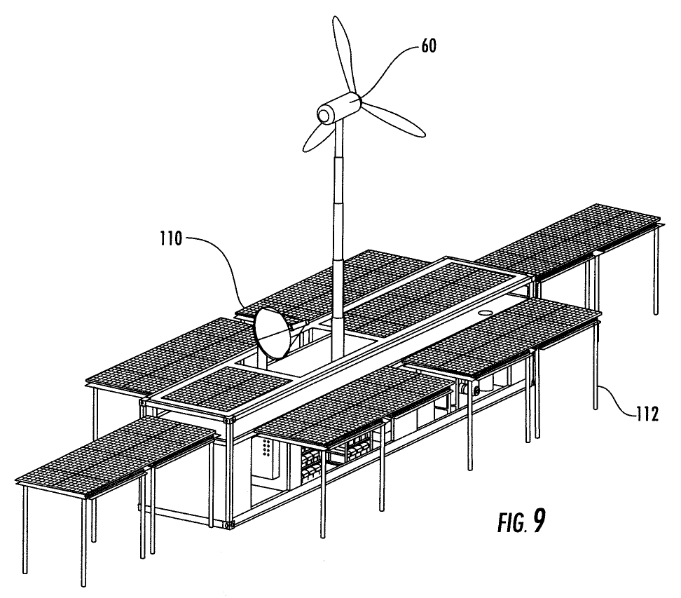

The interior of the container may include a working area 108 (FIG. 8) and/or living quarters for an operating crew/security detail, which provide the basic needs of the crew for continuous occupation of the station (e.g., bathroom, beds, etc.) The interior may also include communications area containing the telecommunication equipment 92 powered by at least one engine/generator designed to run off the power obtained from the solar panels, wind turbine, electrical storage means and/or at least one generator 84. The telecommunication equipment may include, albeit not limited to, a microwave, satellite, two-way radio/TV, and land line connections. All necessary antennae are removably mounted on the container with jacks or telescoping masts. For example, FIGS. 8 and 9 illustrates a user satellite dish removably attached to the top panel of the container by any means known in the art. The satellite enables utilities like VSAT which offer Wi Fi/ VoIP service up to three miles from the unit. The satellite uplink also allows for remote monitoring of the power station. Other communications gear, such as teletype and a facsimile may be included. If the power station is used for disaster response, the communications area would be equipped to provide message service to the public to permit notification of the next-of-kin. This could be a quantity of cell/satellite phones or use of the more sophisticated equipment as a relay.

The water treatment system 76 may be also housed within the container interior and is designed to meet the potable water standards established by the World Health Organization (WHO). According to a preferred, albeit non-limiting example, the water treatment system is powered by at least one engine (Tesla engine) which runs on the energy derived by the solar panels and/or wind turbine. The engine(s) operates the water filtration components, e.g., ozone, ultra filtration, ultraviolet, etc. For example, the station may include a Multiple Stage Filtration (MSF) Process which includes an initial halogen-based chemical treatment for disinfection/deactivation, as described in detail in U.S. patent application Ser. No. 11/264,659 which was previously incorporated by reference. The filtration plant illustrated therein has a capacity to treat approximately 26 gallons per minute (100 LPM) on a batch or continuous flow basis. It should include control systems, sensors which monitor the effluent, and remote monitoring equipment accessible by satellite phone or other means. The water treatment plant automatically bypasses the effluent when unacceptable readings occur. The components in the water filtration unit will be able to process fresh water, remove biological contaminants, heavy metals, and filter water to the micron level. The hollow fiber ultra-filtration unit will remove high molecular weight substances, colloidal material organic and inorganic polymeric molecules.

The resulting potable water is pumped into storage tanks which are connected to the distribution system (not shown). The distribution system terminates in a manifold of valved spigots located on the exterior of the housing structure and easily accessible to the public for drawing potable water. The distribution system has another terminus in the multiple showers located in the container structure in a series of stalls (not shown).

The power station has its own electrical system powered by the energy derived by the solar panels and/or wind turbine and/or at least one motor driven generator 84. The necessary wiring to all the electrical devices on the power station, including lights, radios, water treatment, and electrical receptacles is supplied by a wiring harness connected to the electrical bus. The bus may also have a DC to AC converter and receptacle to plug into a commercial electrical grid, if one is available. The power station may include an electrical distribution system with electrical receptacles located on the exterior of the housing structure and accessible to the public for drawing electricity.

The housing structure would be supplied with a central ventilation system which would include climate control and air sensors for the detection of the air quality and filters for removing air bourne contaminants and heat pump for heating and cooling the inside air of the working or living quarters of the container.

Leveling jacks 96 are located at the corners of the container to anchor and level the structure on site. The jacks may be manual or powered. The jacks also serve as lifting points for airlift. Also provided is external lighting on the housing structure for identification and security.

Referring again to FIG. 9, the power station solar panels may include retractable support legs 112 for enhanced stability. In addition, the area under the deployed panels may function like a porch under which seating may be placed to function as a classroom, chapel, or the like. The deployed panels may also have attachment means along the perimeter for removably attaching mosquito netting, VISQUEEN, or other breathable, protective material for enhanced comfort within the station.

In operation, the mobile power station would be delivered to a devastated area over land, by air, or over water and set-up near a source of water. The station is supplied with enough provisions for the crew and chemicals for the water treatment module. The primary source of electricity should be obtained via the solar panels and/or wind turbine. This enables the station to remain on site for an extended period of time. The crew of one, two or more personnel would be trained in setting up the station and operating the systems without support or using local help. The crew services the systems on board including deploying the solar panel arrays and wind turbines, replenishing the water treatment chemicals and removing waste products for disposal. In addition, the services of the station would be continuously available to the public according to their needs.

The power station is a natural gathering place for survivors as they come to get water, take a shower, and make necessary calls. The station's communications system links the people with the outside world and keeps them abreast of developments affecting them. For example, a large TV can be mounted on the container. In addition, the communications serve to call for evacuation of medical emergencies.

This includes telecommunication equipment, such as microwave, satellite, two-way radio/TV, teletype, facsimile and land line connections. All the necessary antennae are mounted on the roof of this area. Within the container is the water treatment equipment 76 which is provided with an inlet for the introduction of non-potable water. Doors 66 may be provided on all sides for access to the equipment.

Although not shown in the aforementioned figures, all the electrical connectors, leads, cabling, control systems, transformers, have been provided and need not be discussed further here in the interest of the brevity.

All patents and publications mentioned in this specification are indicative of the levels of those skilled in the art to which the invention pertains. All patents and publications are herein incorporated by reference to the same extent as if each individual publication was specifically and individually indicated to be incorporated by reference.

It is to be understood that while a certain form of the invention is illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

What is claimed is:

1. A portable, self sustaining power station comprising: a transportable container; a plurality of solar panels storable within said container; means for deployment of said solar panels from a storage position to a sunlight collecting position; a wind turbine positioned storable within said container; means for positioning said wind turbine from a storage position to a windward collecting position; batteries electrically coupled to said solar panels and said wind turbine storing electrical energy generated therefrom; and a telecommunication system coupled to said storage batteries.
